(19) United States
(12) Patent Application Publication
(10) Pub. No.: US 2020/0282903 A1
(43) Pub. Date: Sep. 10, 2020

(54) Light Guide for Crossing Light in Backlight Prism

(71) Applicants: DENSO International America, Inc., Southfield, MI (US); DENSO CORPORATION, Kariya-City (JP)

(72) Inventors: Zakary GERTLAR, Birmingham, MI (US); Jill GARCIA, Waterford, MI (US)

(21) Appl. No.: 16/296,274

(22) Filed: Mar. 8, 2019

(51) Int. Cl. B60Q 3/14; F21V 7/00; H05K 1/18

(52) U.S. Cl. CPC B60Q 3/14; F21V 7/0008; H05K 2201/10106; B60K 2350/203; H05K 1/181

(57) ABSTRACT

An instrument cluster assembly includes first and second light emitting elements. The first and second light emitting elements are spaced apart from one another. An optical element is positioned opposite the first and second light emitting elements. The optical element is configured to reflect or diffuse light from both the first and second light emitting elements so that light rays from the first and second light emitting elements are merged or cross one another.

### FIELD

The present disclosure relates to a prism to reflect and/or diffuse light emitted by a light emitting element of, for example, an instrument cluster assembly.

### BACKGROUND

Instrument cluster assemblies, such as for motor vehicles, include light emitting elements to illuminate various dials and/or gauges. While such light emitting elements are suitable for their intended use, they are always subject to improvement. For example, an instrument cluster assembly, including multiple light emitting elements configured to provide improved illumination to dials and gauges with a reduced number of light reflectors and/or diffusers, that have increased effectiveness, would be desirable.

### SUMMARY

The present disclosure provides an instrument cluster assembly comprising a first and second light emitting element. The first and second light emitting elements are spaced apart from one another. An optical element is positioned opposite to the first and second light emitting elements. The optical element is configured to reflect or diffuse light rays from both the first and second light emitting elements so that the light rays from the first and second light emitting elements are merged or crossed with one another. The optical element further comprises a pair of light guides to merge or cross the light rays. The pair of light guides direct the light rays to an optical layer. The first and second light emitting elements each include a pair of light emitting diodes. The first and second light emitting elements are mounted on a circuit board. The optical element may be a prism. An angled surface is positioned on the light guides to direct the light rays.

Further areas of applicability will become apparent from the description provided herein. The description and specific examples in this summary are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

FIG. 1 is an exploded view of an instrument cluster assembly.

FIG. 2 is a perspective schematic view of the partial view of the instrument cluster assembly

FIG. 3 is a front plan view of the optical layer.

FIG. 4 is a rear plan view of FIG. 3.

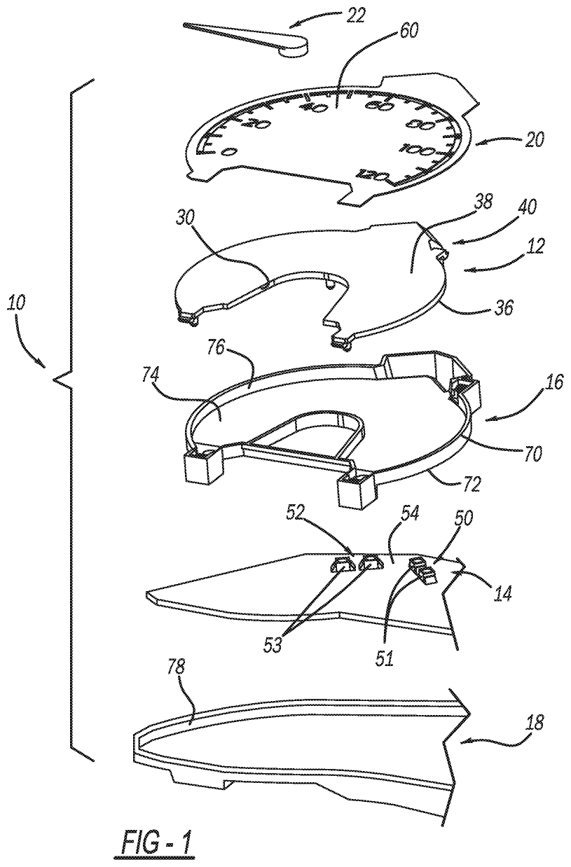

### DETAILED DESCRIPTION

Example embodiments will now be described more fully with reference to the accompanying drawings.

Turning to the figures, an instrument cluster assembly is illustrated and designated with the reference numeral 10. The instrument cluster assembly 10 generally includes an optical layer or disk 12, a circuit board 14, a reflective case including a reflective case body 16 and a reflective case base 18. A dial or applique 20, as well as a pointer 22, is included. The pointer 22 is mounted to a rotating member 24 such as a post extending through the aperture 30 in the optical layer. The rotating member can be rotated in a suitable manner by a suitable device such as a step motor. The aperture may also accommodate additional posts for rotating additional pointers.

The optical layer 12 includes a first side 36 and a second side 38. An optical element 40 extends from the first side 36. The second side 38 may include the applique 20 or be embossed with numerals or the like. The optical element 40 can be any suitable element, device, or structure, for example, configured to reflect and/or diffuse light, such as a prism for example. The optical element 40 will be described in further detail.

The circuit board 14 includes a first light emitting element 50 and a second light emitting element 52. The first and second light emitting elements 50, 52 are at the outer surface 54 of the circuit board 14, which is opposite to an inner surface 36. The first and second light emitting elements 50, 52 can be any suitable light source, such as a semiconductor light source including light emitting diodes LEDs. The first and second light emitting elements 50, 52 can be configured to emit light having the same color or different colors. The first and second light emitting elements 50, 52 can also be configured to emit light having the same or similar intensities, or different intensities or orientations. Further, the first and second light emitting elements 50, 52 can be configured to emit light having only one color or multiple colors. The first and second light emitting elements 50, 52 are shown include a pair of light sources 51, 53. Preferably, light sources 51, 53 are LEDs However, any multitude of LEDs may be arranged to provide the emitted light. One, two, three or more LEDs may be positioned to emit light to the optical element 40.

The first and second light emitting elements 50, 52 are configured and arranged to illuminate graphics of the applique 20 or optical layer 12. The applique and/or graphics are thus configured and arranged so they are leased partially transparent to light emitted from the first and second light emitting elements 50, 52. The graphics 60 can be configured to convey a variation of information, such as a speed of the vehicle that the instrument cluster assembly is associated with. The pointer 22 can be configured to designate, for example, the appropriate graphic 60 representing the current speed of the vehicle.

The reflector case body 16 includes an outer surface 70 and an inner surface 72. The reflective case body 16 defines a recess beneath the outer surface 70. The recess 74 includes reflective sidewalls 76 that configured to direct light emitted from the first and second light emitting elements 50, 52 to the applique 20.

The reflective case body 16 is generally between the optical layer 12 and the circuit board 14. The optical layer 12 is arranged such that the first side is at or approximate to the outer surface of the reflective case body 16 and the optical element 40 of the optical layer 12 extends into the recess 74. The circuit board 14 is arranged such that the first and second light emitting elements 50, 52 extend through, or are aligned with, one or more openings defined in the inner surface of the reflective body 16. The first and second light emitting elements 50, 52 are spaced apart from one another. The optical element 40 is arranged generally opposite to the outer surface 54 of the circuit board 14. The optical element 40 is arranged opposite to the first and second light emitting elements 50, 52. The reflective case body 16, the optical layer 12 and the circuit board 14 are seated within a receptacle 78 on the reflective case base 18. The circuit board 14 is seated furthest within the receptacle 78. The applique 20 is seated above the second side 38 of the optical layer 12.

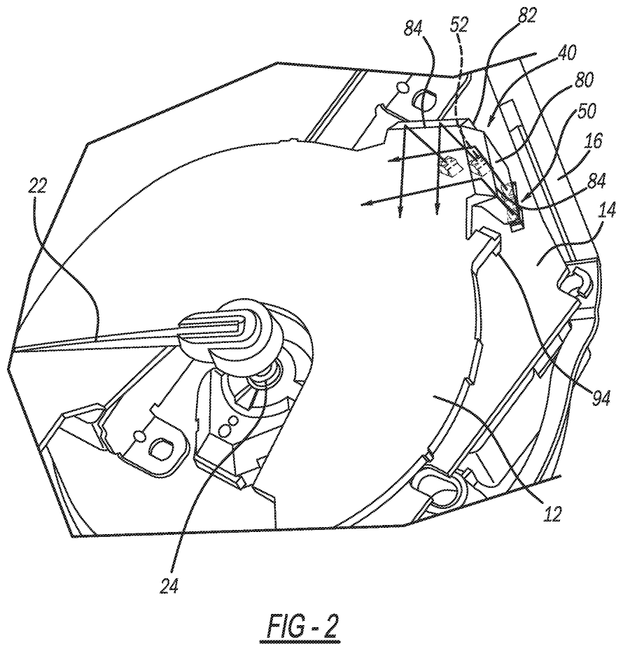

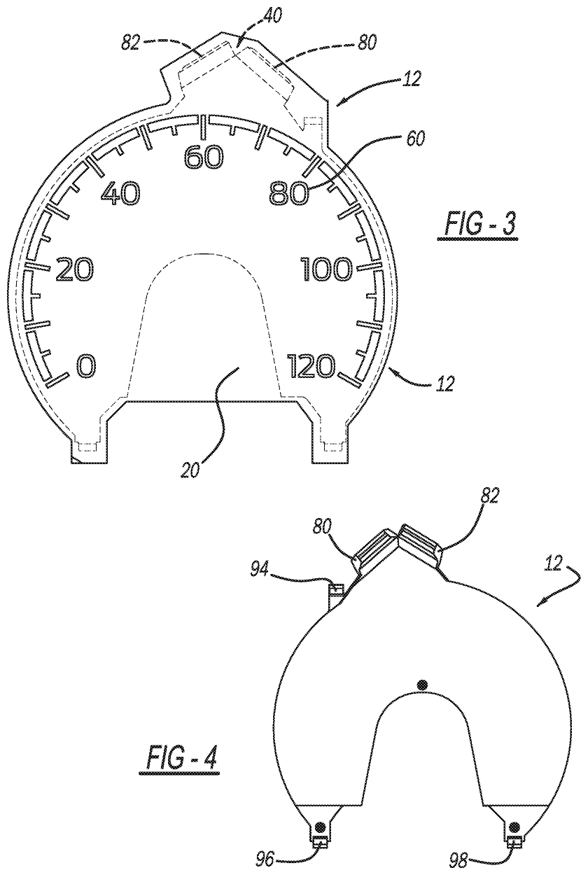

Turning to FIGS. 2-4, additional features of the optical element 40 will be discussed. The optical element 40 includes two separate light guides or light pipes 80, 82. The two separate light guides 80, 82 may be substantially identical or may vary from one another. The light guides 80, 82 are positioned directly adjacent the light emitting elements 50, 52. The light guides 80, 82 include an angled surface 84 to diffuse the light rays from the first and second light emitting elements 50, 52. As the light rays are reflected or diffuse from the angled surfaces 84, the light rays merge or cross one another in the optical layer 12. This distributes the light through the prisms. As the light rays cross one another, they fully illuminate, or backlight, the other prism behind the applique or graphics, backlighting the instrument cluster. Thus, the light rays become crossed and are sent in opposing directions in order to fill the prism. While the aforementioned light emitting LEDs 50, 51, 52, 53 are in pairs in the example demonstrated here, they could be used in any combination in order (1, 2, 3, etc.) to achieve the preferred final lighting condition of the applique or graphics above.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

1. An instrument cluster assembly comprising:
a first and second light emitting elements, the first and second light emitting elements spaced apart from one another; and
an optical layer including an optical element, the optical element positioned opposite to the first and second light emitting elements, the optical element including angled surfaces to reflect or diffuse light from both the first and second light emitting elements so that light rays from the first and second light emitting elements are projected from the optical element to the optical layer so that the light rays are merged or cross one another in the optical layer illuminating fully the optical layer to illuminate the instrument cluster.

2. The instrument cluster assembly of claim 1, the optical element further comprising a pair of light guides to merge or cross the light rays.

3. The instrument cluster assembly of claim 2, wherein the pair of light guides direct the light rays to the optical layer.

4. The instrument cluster assembly of claim 1, wherein the first and second light emitting elements each include at least one light emitting source.

5. The instrument cluster assembly of claim 1, wherein the first and second light emitting elements are mounted on a circuit board.

6. The instrument cluster assembly of claim 1, wherein the optical element is a prism.

7. The instrument cluster assembly of claim 2, further comprising an angled surface on the light guides for directing the light rays.

8. The instrument cluster assembly of claim 1, wherein at least one of the first and second light emitting elements include at least two light emitting sources.

9. The instrument cluster assembly of claim 8, wherein the light emitting sources are diodes.
